(19) United States
(12) Patent Application Publication
(10) Pub. No.: US 2026/0282515 A1
(43) Pub. Date: Sep. 17, 2026

(54) HIGH PERFORMANCE POWER MOSFET WITH INTEGRATED SBD

(71) Applicant: Microchip Technology Incorporated, Chandler, AZ (US)

(72) Inventor: Shesh Mani Pandey, Gilbert, AZ (US)

(73) Assignee: Microchip Technology Incorporated, Chandler, AZ (US)

(21) Appl. No.: 19/555,277

(22) Filed: Mar. 3, 2026

Related U.S. Application Data
(60) Provisional application No. 63/773,260, filed on Mar. 17, 2025.

(51) Int. Cl. H10D 84/00; H10D 8/60; H10D 30/63; H10D 62/10; H10D 64/27; H10D 64/66; H10D 8/01; H10D 30/01; H10D 84/01

(52) U.S. Cl. CPC H10D 84/101; H10D 8/60; H10D 30/63; H10D 62/124; H10D 64/514; H10D 64/661; H10D 8/051; H10D 30/025; H10D 84/0109

(57) ABSTRACT

A semiconductor device comprises a volume of semiconductor material, an integrated metal oxide semiconductor field-effect transistor (MOSFET), and an integrated Schottky barrier diode (SBD). The volume of semiconductor material includes a first end, a second end spaced vertically below the first end, a first side, and a second side spaced laterally from the first side. The volume of semiconductor material includes an upward projection spaced from the first side. The MOSFET includes a first transistor side located adjacent the first side of the volume of semiconductor material. The first transistor side includes a first well and a first gate. The SBD comprises a Schottky material positioned over at least part of the upward projection.

### CROSS-REFERENCE TO RELATED APPLICATIONS

The current patent application claims priority to and the benefit of U.S. Provisional Application Ser. No. 63/773,260 titled “HIGH PERFORMANCE POWER MOSFET WITH INTEGRATED SBD” and filed Mar. 17, 2025. The Provisional Application is hereby incorporated by reference, in its entirety, into the current patent application.

### TECHNICAL FIELD

The present disclosure relates to semiconductor devices including a metal oxide semiconductor field-effect transistor (MOSFET) and methods of making them. More particularly, the various examples described herein concern a device including a power MOSFET and an integrated Schottky barrier diode (SBD).

### BACKGROUND

A MOSFET is an active, voltage-controlled semiconductor device, in which varying an electrical voltage between a gate and a body controls an electrical current flowing through a semiconductor channel between a drain and a source. Applications for MOSFETs include amplifiers, switches, resistors, regulators, oscillators, choppers, and more. It is generally desirable to improve the performance and to reduce the cost of MOSFETs, but it can be difficult to do so.

This background discussion is intended to provide information related to the present disclosure, which is not necessarily prior art.

### SUMMARY

According to the present disclosure, a semiconductor device may include a volume of semiconductor material, an integrated metal oxide semiconductor field-effect transistor (MOSFET), and an integrated Schottky barrier diode (SBD). The volume of semiconductor material may include a first end (e.g., a top), a second end spaced vertically below the first end (e.g., a bottom), a first side (e.g., a left side), and a second side spaced laterally from the first side (e.g., a right side). The volume of semiconductor material may also include an upward projection spaced from the first side such that the first end includes an upper portion spaced from the first side and a first portion located between the upward projection and the first side. The first portion of the first end may be located closer to the second end than the upper portion. The integrated MOSFET may include a first transistor side located adjacent to the first side of the volume of semiconductor material. The first transistor side may include a first well and a first gate. The first well may be located adjacent to the first end of the volume of semiconductor material. The integrated SBD may comprise a Schottky material positioned over at least part, or portion, of the upward projection of the volume of semiconductor material.

This summary is not intended to identify essential features of the examples, and is not intended to be used to limit the scope of the claims. These and other aspects of the present examples are described below in greater detail.

### BRIEF DESCRIPTION OF THE DRAWINGS

Examples are described in detail below with reference to the attached drawing figures, wherein:

FIG. 1 illustrates an example device including a power MOSFET and an integrated SBD, in accordance with the present disclosure;

FIG. 2 illustrates an example method of forming the device of FIG. 1, in accordance with the present disclosure;

FIG. 3a illustrates an intermediate operation in forming a volume of semiconductor material as part of the device of FIG. 1 via the method of FIG. 2;

FIG. 3b illustrates another intermediate operation in forming the device of FIG. 1 via the method of FIG. 2;

FIG. 3c illustrates another intermediate operation in forming the device of FIG. 1 via the method of FIG. 2;

FIG. 3d illustrates another intermediate operation in forming the device of FIG. 1 via the method of FIG. 2;

FIG. 3e illustrates another intermediate operation in forming the device of FIG. 1 via the method of FIG. 2; and

FIG. 3f illustrates a final operation in forming the device of FIG. 1 via the method of FIG. 2.

The figures are not intended to limit the examples to the specific details illustrated therein. The drawings are not necessarily to scale.

### DETAILED DESCRIPTION

In the following detailed description, reference is made to the accompanying drawings, which form a part hereof and in which are shown, by way of illustration, specific examples in which the present disclosure may be practiced. These examples are described in sufficient detail to enable a person of ordinary skill in the art to practice the present disclosure. However, other examples may be utilized, and structural, material, and process changes may be made without departing from the scope of the disclosure. Unless clearly understood or expressly identified otherwise, structures, materials, procedures, operations, and other aspects described in the context of one example may be incorporated into other examples.

The illustrations presented herein are not meant to be actual views of any particular method, system, device, or structure, but are merely idealized representations that are employed to describe the examples of the present disclosure. The drawings presented herein are not necessarily drawn to scale. Similar structures or components in the various drawings may retain the same or similar numbering for the convenience of the reader; however, the similarity in numbering does not mean that the structures or components are necessarily identical in size, composition, configuration, or any other property.

Terms of relative location and direction (e.g., above, below, left, right, upper, lower, vertical, lateral, horizontal) may be used to facilitate the present descriptions of examples with reference to the figures, but unless clearly understood or expressly identified otherwise, these terms are not meant to be limiting with regard to location, direction, or overall orientation, and may, for example, change as a result of a change in overall orientation.

The following description may include examples to help enable one of ordinary skill in the art to practice the disclosed examples. The use of the terms "exemplary," "by example," and "for example," means that the related description is explanatory, and though the scope of the disclosure is intended to encompass the examples and legal equivalents, the use of such terms is not intended to limit the scope of an example or this disclosure to the specified components, operations, features, functions, or the like.

It will be readily understood that the components of the examples as generally described herein and illustrated in the drawings could be arranged and designed in a wide variety of different configurations. Thus, the following description of various examples is not intended to limit the scope of the present disclosure but is merely representative of various examples.

The term “signal” or “electronic signal” may be used to describe electrical energy conducted through an electrically conductive medium in which an electric voltage and/or an electric current varies, or may be constant, over time. An electronic signal may be an electromagnetic wave, voltage, and/or current, and may be encoded with or representative of information.

Broadly, examples presented herein are directed toward forming semiconductor devices from a volume of semiconductor material by physically and functionally integrating a MOSFET and a SBD. The various examples of the present disclosure described herein are directed to semiconductor devices, such as those including a power MOSFET formed from a volume of semiconductor material, and including a SBD. The volume of semiconductor material may include may include an upward projection between the first and second sides thereof, and the SBD may be positioned over at least a portion of the upward projection. The examples may also include methods of making the device described above. Power devices that are the subject of the various examples disclosed herein may be more rugged and offer higher performance when compared to conventional power MOSFETs formed via convention processes. For instance, the power devices disclosed herein may offer lower capacitance (e.g., gate-drain capacitance, or C_{gd}) and/or expose any gate oxides included therein to substantially lower electric fields when compared to conventional power MOSFETs.

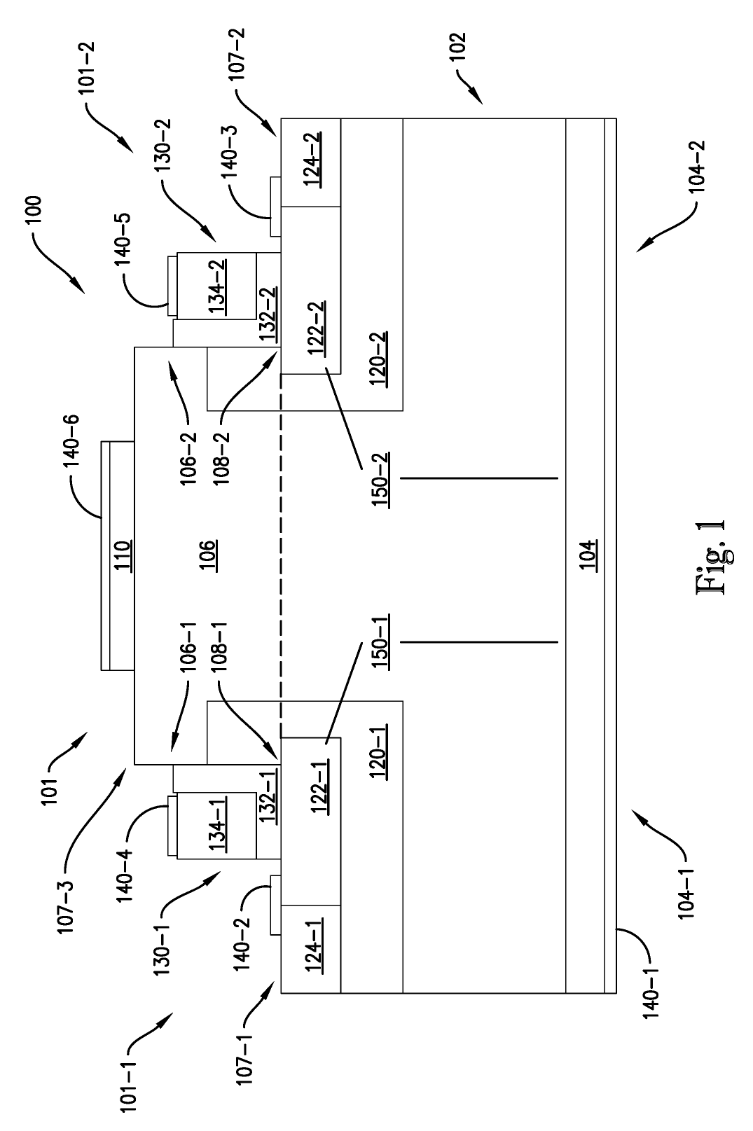

FIG. 1 illustrates an example of a semiconductor device 100 in accordance with the present disclosure. The semiconductor device 100 includes a MOSFET 101, which may comprise a first and second transistor side 101-1, 101-b. The device 100 further includes a volume of semiconductor material 102. The first transistor side 101-1, which is located adjacent to the first end and the first side of the volume of semiconductor material 102, includes a first drain, or drain region, 104-1; a first well, or well region, 120-1; a first source, or source region, 122-1; a first body contact, or body, 124-1; a first gate, or gate region, 130-1; and a first channel 150-1. Similarly, the second transistor side 101-2, which is located adjacent to the first end and the second side of the volume of semiconductor material 102, includes a second drain, or drain region, 104-2; a second well, or well region, 120-2; a second source, or source region, 122-2; a second body contact, or body, 124-2; a second gate, or gate region, 130-2; and a second channel 150-2. Unless otherwise specified, first and second transistor sides 101-1, 101-2 may be symmetrical to each other in terms of the geometry (e.g., size and shape) of the components, features, and/or regions included therein (e.g., wells, sources, bodies, and so on, without limitation) and may utilize the same material composition(s) for the components, features, and/or regions. However, it will be appreciated that various asymmetries in geometry, quantity, and/or composition of any components, features, and/or regions between the first and second transistor sides may be within the ambit of certain aspects of the example device. An integrated SBD 110 is also included integrated into the device 100.

It is also noted that, with the transistor sides 101-1 and 101-2, the illustrated MSOFET 101 is a so-called dual channel MOSFET. However, according to certain examples, the MOSFET may alternatively be a single channel transistor, in which only a single source, well, and body contact are provided within the volume of semiconductor material.

The volume of semiconductor material 102 may be formed, e.g., via epitaxial growth, or otherwise provided on a substrate 104, which may also be epitaxially grown or otherwise provided. The volume of semiconductor material 102 may comprise, or be formed of, an N-type material. The substrate 104 may comprise, or be formed of, an N+ material.

The volume of semiconductor material 102 may include a first end, a second end spaced vertically below the first end be formed, a first side, and a second side spaced laterally from the first side. The volume of semiconductor material 102 includes an upward projection 106. The upward projection 106 of the volume of semiconductor material 102 includes all portions, or regions, of the volume of semiconductor material 102 positioned above the dashed, or dotted, line, as illustrated in FIG. 1. The upward projection 106 may include parts of various features, or regions, typically found in semiconductor devices, such as wells, sources, bodies, and so on, or combinations thereof, without limitation. As illustrated, part of first and second wells, or well regions, 120-1, 120-2 are included in upward projection 106. It will be appreciated that the dashed line in FIG. 1 is merely included to serve as a visual aid in distinguishing between the upward projection 106 and the remainder of the volume of semiconductor material 102.

First and second vertical sides 106-1, 106-2 of the upward projection 106 separate the first end, or top, of the volume of semiconductor material 102 into three (3) distinct sections – a first portion 107-1, a second portion 107-2, and an upper portion 107-3. As illustrated, the first and second portions 107-1, 107-2 of the first end of the volume of semiconductor material 102 are correspondingly spaced a first and second dimension from the second end of the volume of semiconductor material 102. As illustrated, the first and second dimensions may be equal, although certain examples contemplate side portions 107-1, 107-2 having different heights (i.e., being spaced dissimilarly from the second end of the volume of semiconductor material). Further, the upper portion 107-3 of the first end is spaced at a third dimension from the second end of the volume of semiconductor material 102, with the third dimension being greater than the first and second dimensions. Further, the central portion 107-3 of the first end may be spaced equally between the first and second sides of the volume of semiconductor material 102, although certain aspects contemplate dissimilar spacing, wherein one of the side portion 107-1, 107-2 is longer than the other.

In other words, as illustrated, first and second portions 107-1, 107-2 may be at the same height, or level, relative to each other while the upper portion 107-3 is at a greater height, or level, than the first and second portions 107-1, 107-2. Accordingly, the side portions 107-1, 107-2 are closer to the second end (e.g., bottom) of the volume of semiconductor material 102 than the central portion 107-3. Further, upper portion 107-3 is centered between first and second portions 107-1, 107-2.

The first portion 107-1 of the first end is located between the first vertical side 106-1 of the upward projection 106 and the first side of the volume of semiconductor material 102. Similarly, the second portion 107-2 of the first end is located between the second vertical side 106-2 of the upward projection 106 and the second side of the volume of semiconductor material 102. In certain examples, one of the vertical sides of the upward projection may be aligned with one of the sides of the volume of semiconductor material, such that one of the side portions of the first end of the volume of semiconductor material is entirely eliminated (which may be a suitable configuration for a single channel MOSFET). The upper portion 107-3 of the first end is located between the first and second vertical sides 106-1, 106-2 of the upward projection 106.

The first and second vertical sides 106-1, 106-2 of upward projection 106 extend upwardly from the corresponding first or second portion 107-1, 107-2 of volume of semiconductor material 102, and cooperate therewith to define first and second inner corners 108-1, 108-2, respectively. Although identified as inner “corners” and illustrated as ninety-degree (90^{o}) sharp angles, the term “corners” may be interpreted to include any concave shape defined between each vertical side of the upward projection and the corresponding portion of the upper end. In other words, according to certain aspects of the example semiconductor device, the term “inner corner” shall not be limited to a sharp apex or a ninety degrees (90º) angle. One will further appreciate that each of the first and second inner corners may be rounded, chamfered, beveled, clipped, or otherwise multi-faceted and/or may measure more or less than ninety degrees (90^{o}) without departing from the present disclosure.

The SBD 110 comprises a Schottky material. In various examples of the present disclosure, the Schottky material may be a metal from the group consisting of: titanium, molybdenum, platinum, chromium, tungsten, aluminum, and combinations thereof. The SBD 110 may be spaced equally between the first and second vertical sides 106-1, 106-2 of the upward projection 106. However, according to certain examples, the SBD may span the full extent (width) of the upper portion 107-3 of the first end or may be offset on the upper portion 107-3 (spaced closer to one vertical side than the other. Size, shape, and composition of the SBD 110 may vary within the parameters described in this paragraph without departing from the scope of the present disclosure.

The SBD 110 may be positioned over at least a part, or portion, of the upward projection 106. Accordingly, the SBD may overlay at least part of the upper portion 107-3 of the first end of the volume of semiconductor material 102.

The first and second wells 120-1, 120-2 are located adjacent to the first end and the corresponding first or second side of the volume of semiconductor material 102. More particularly, the first well 120-1 is located adjacent to the first portion 107-1 of the top of the volume of semiconductor material 102 and the first vertical side 106-1 of the upward projection 106. The first well 120-1 extends along part of the first inner corner 108-1, and extends along at least part of the first vertical side 106-1 of the upward projection 106. Further, the first well region 120-1 can be thought of as including a vertical well portion and a horizontal well portion, with the vertical well portion extending along at least part of the first vertical side 106-1 of the upward projection 106, and the horizontal well portion being positioned at least partially below the first source 122-1. The first well 120-1 may comprise, or be formed of, a P-type material.

Analogously, and more particularly, the second well 120-2 is located adjacent to the second portion 107-2 of the top end of the volume of semiconductor material 102 and the second vertical side 106-2 of the upward projection 106. The second well 120-2 extends along part of the second inner corner 108-1, and extends along at least part of the second vertical side 106-2 of the upward projection 106. The second well region 120-2 can also be thought of as including a vertical well portion and a horizontal well portion, with the vertical well portion extending along at least part of the second vertical side 106-2 of the upward projection 106, and the horizontal well portion being positioned at least partially below the second source 122-2. The second well 120-2 may comprise, or be formed of, a P-type material.

First and second sources 122-1, 122-2 are positioned adjacent to, and extend along, at least part of the corresponding first or second portion 107-1, 107-2 of the first end of the volume of semiconductor material 102. The first and second sources 122-1, 122-2 extend along part of the corresponding first or second inner corner 108-1, 108-2. In various examples of the present disclosure, the first and second sources 122-1, 122-2 extend laterally away from the corresponding first or second side of the volume of semiconductor material and beyond, or past, the corresponding first or second vertical sides 106-1, 106-2 of upward projection 106. According to certain examples, the extent to which each of the sources 122-1, 122-2 extends past the corresponding vertical side 106-1, 106-2 may vary or be eliminated altogether. The first and second sources 122-1, 122-2 may comprise, or be formed of, an N+ material.

The first and second body contacts 124-1, 124-2 extend along the corresponding first or second portion 107-1, 107-2 of the first end of the volume of semiconductor material and between the corresponding source 122-1, 122-2 and the corresponding first or second side of the volume of semiconductor material 102. According to certain examples, the source regions 122-1, 122-2 may instead extend all the way to the corresponding side of the volume of semiconductor material 102, such that the body contacts 124-1, 124-2 are otherwise located or eliminated altogether. The first and second body contacts 124-1, 124-2 may comprise, or be formed of, a P+ material.

The first and second gates 130-1, 130-2 may be located, or formed, within the corresponding first or second inner corners 108-1, 108-2. The first gate, or gate region, 130-1, includes a layer of dielectric material (e.g., a gate dielectric) 132-1. The layer of dielectric material 132-1 includes (i) an upright dielectric portion extending upwardly, or vertically in the illustrated example, along the first vertical side 106-1 of the upward projection 106, and (ii) a lateral dielectric portion extending laterally, or horizontally in the illustrated example, along at least part of the first portion 107-1 of the first end of volume of semiconductor material 102. The first gate 130-1 also includes a gate structure 134-1 positioned along the vertical and horizontal dielectric portions. The gate structure 134-1 may comprise, or be formed of, a polysilicon material. In various examples of the present disclosure including those consistent with the MOSFET 101 illustrated in FIG. 1, the vertical dielectric portion of the first gate 130-1 extends upwardly along the first vertical side 106-1 of the upward projection 106 beyond, or past, the gate structure 134-1.

Analogously, the second gate region 130-2 includes a layer of dielectric material 132-2. The layer of dielectric material 132-2 includes (i) an upright dielectric portion extending upwardly, or vertically in the illustrated example, along the second vertical side 106-2 of the upward projection 106, and (ii) a lateral dielectric portion extending laterally, or horizontally in the illustrated example, along at least part of the second portion 107-2 of the first end of volume of semiconductor material 102. The second gate 130-2 also includes a gate structure 134-2 positioned along the vertical and horizontal dielectric portions. The gate structure 134-2 may comprise, or be formed of, a polysilicon material. In various examples of the present disclosure including those consistent with the MOSFET 101 illustrated in FIG. 1, the vertical dielectric portion of the second gate 130-2 extends upwardly along the first vertical side 106-1 of the upward projection 106 beyond, or past, the gate structure 134-2.

The device 100 further includes electrical terminals, or contacts, 140-1, 140-2, 140-3, 140-4, 140-5, 140-6 to facilitate the application of various electrical signals to the substrate 104, first source 122-1, second source 122-2, first gate 130-1, second gate 130-2, and SBD 110, respectively. The addition, or application, of electrical contact 140-1 to substrate 104 may form first and second drains, or drain regions, 104-1, 104-2. The first drain 104-1 may serve as the drain for the first transistor side 101-1, while the second drain 104-2 may serve as the drain for the second transistor side 101-2. Although listed as two separate drains, the first and second drains 104-1, 104-2 may comprise a single, continuous drain spanning the entirety of the substrate 104. The electrical contacts 140-1, 140-2, 140-3, 140-4, 140-5, 140-6 may comprise, or be formed of, a contact metal.

In operation, when a gate-source voltage (V_{gs}) is applied between one or more of the source terminals 140-2, 140-3 and one or more of the gate terminals 140-4, 140-5, the generated electric field creates an inversion layer at the semiconductor-dielectric interface. The inversion layer may provide a channel(s) 150-1, 150-2 through which electrical current can flow when a drain-source voltage (V_{ds}) is applied between one or more of the source terminals 140-2, 140-3 and the drain terminal 140-1. More specifically, V_{gs} controls the width of a depletion region at the P-N junction where the charge carriers of the P- and N-type materials diffuse into each other, which depletes the available concentration(s) of majority charge carrier in each material, thereby controlling a current (I_{d}) that flows between one or more of the drains/drain regions 104-1, 104-2 and the corresponding source/source region 122-1, 122-2 to form corresponding channel 150-1, 150-2.

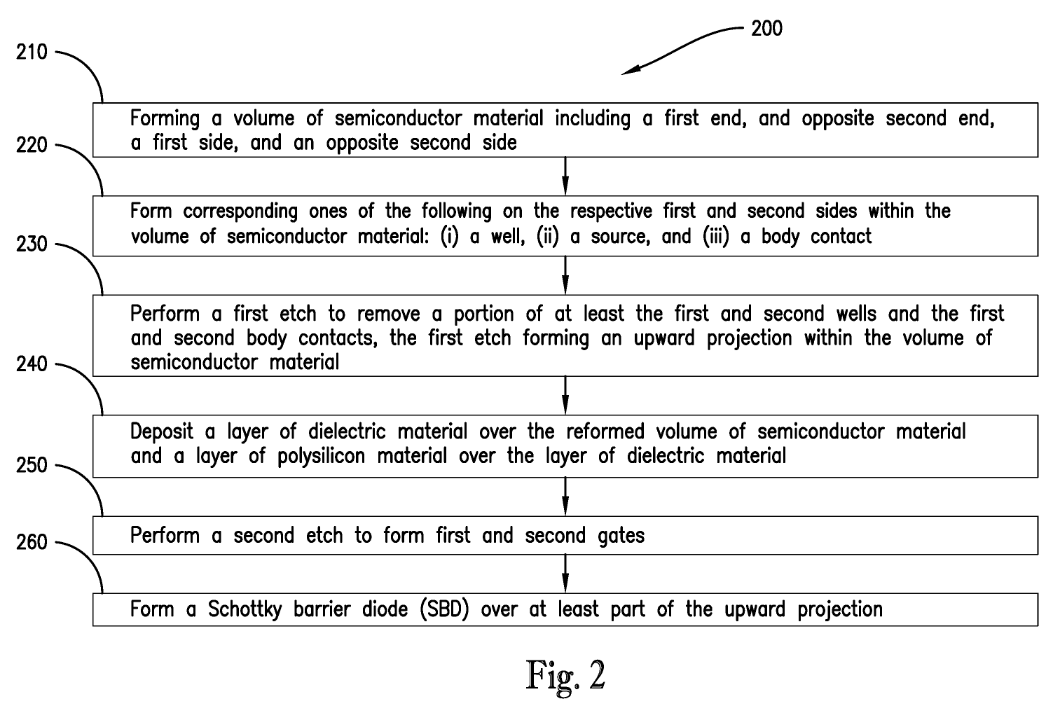

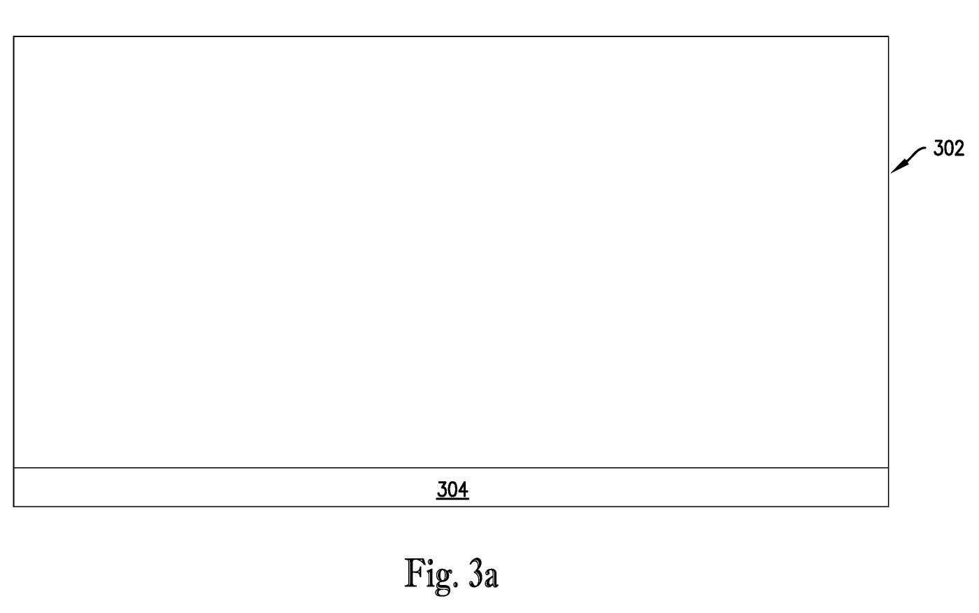

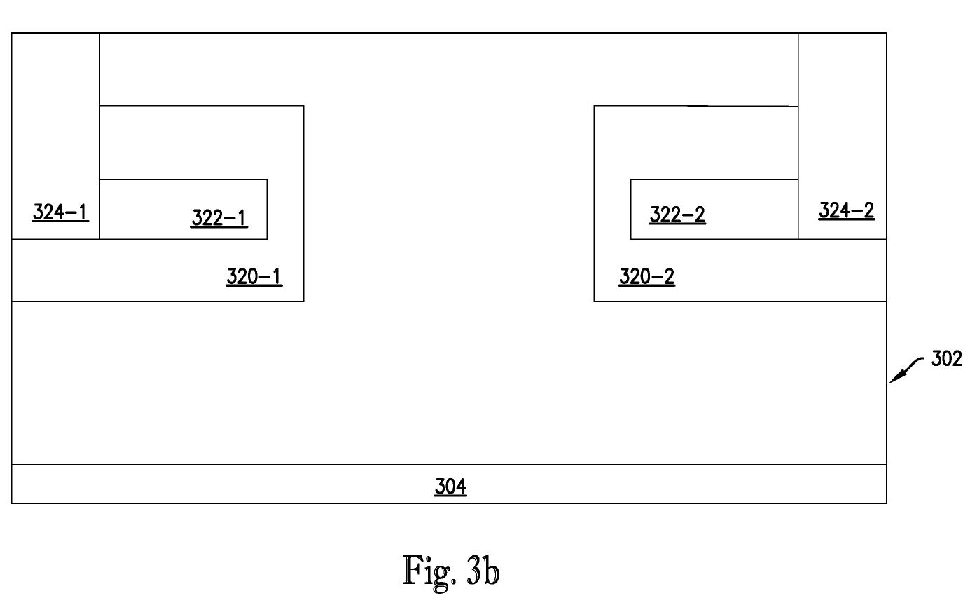

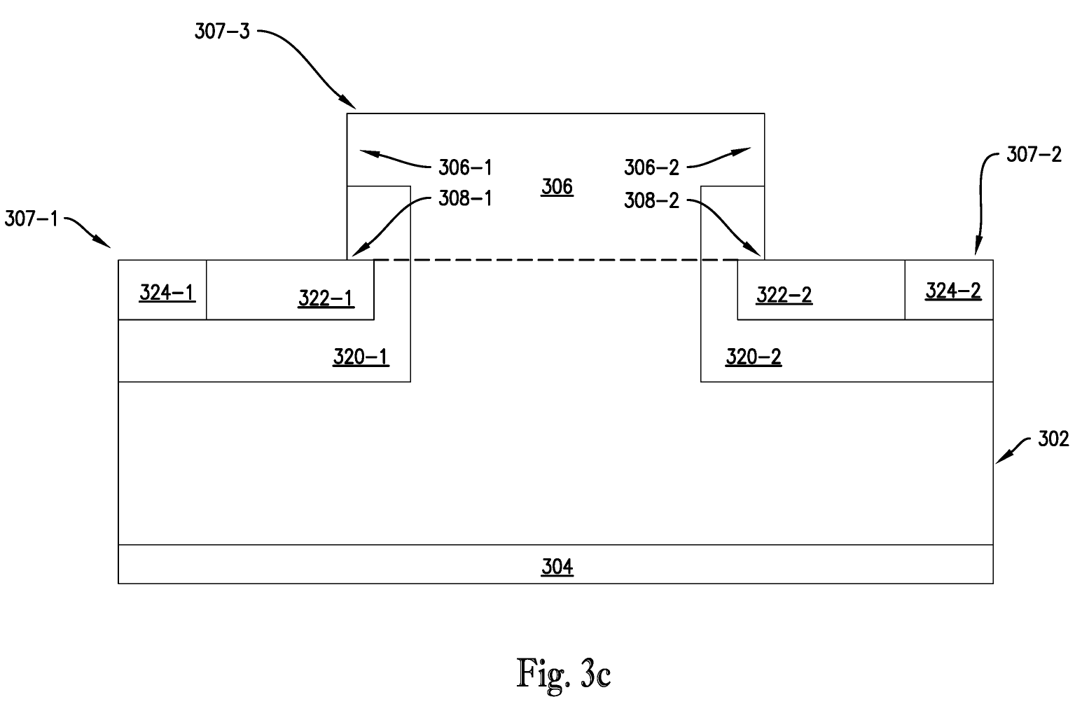

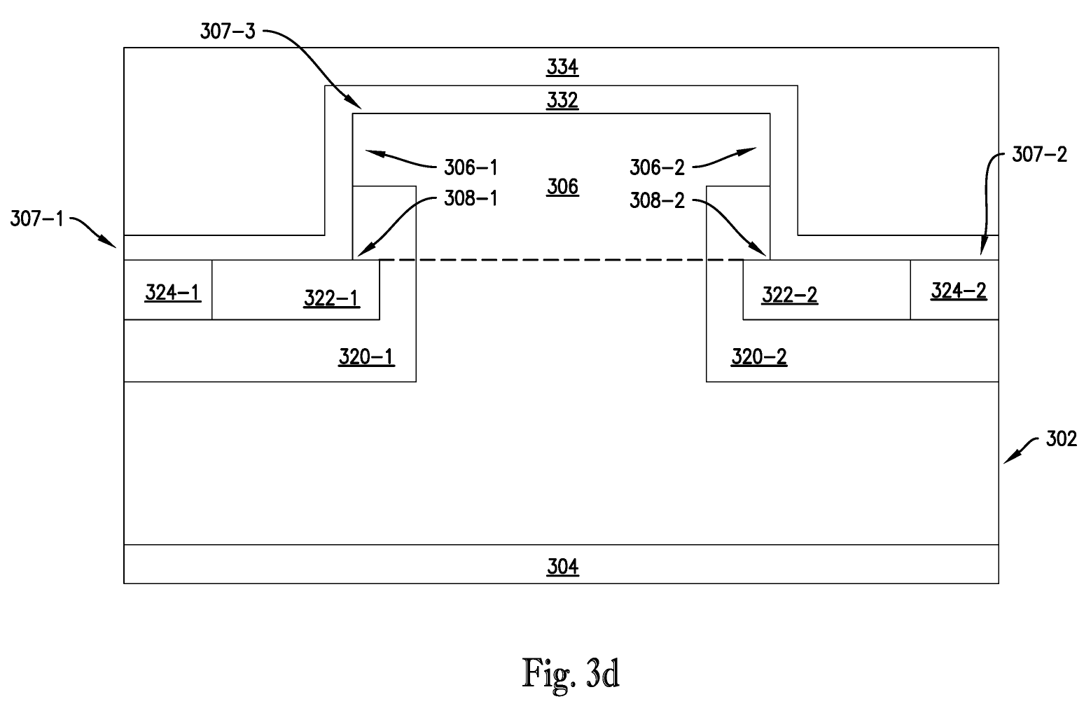

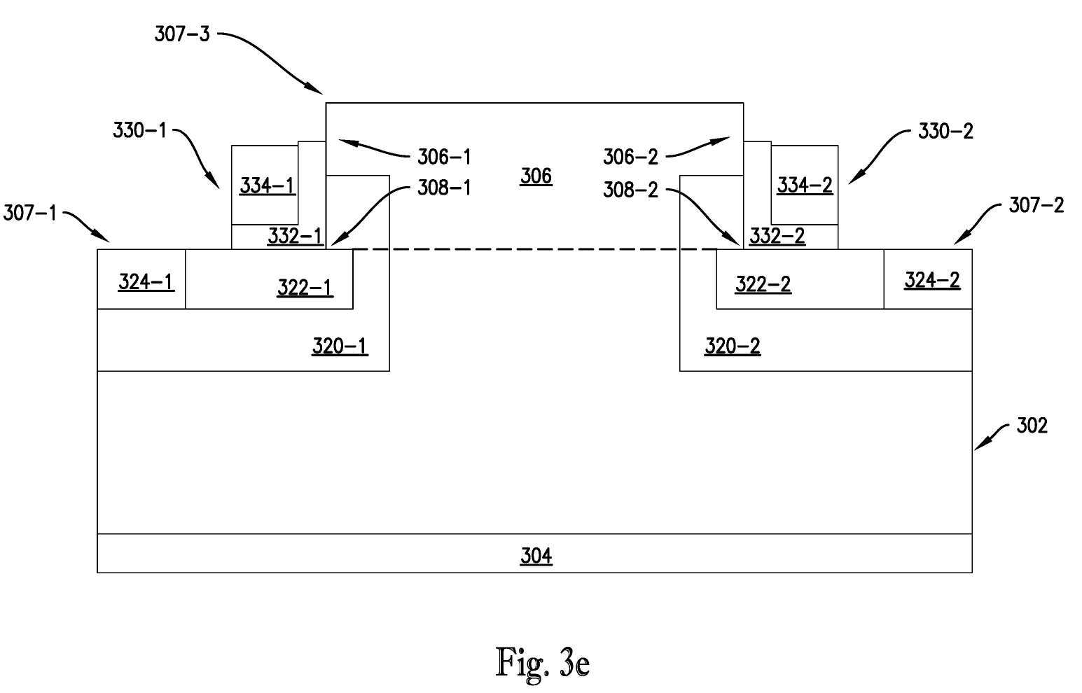

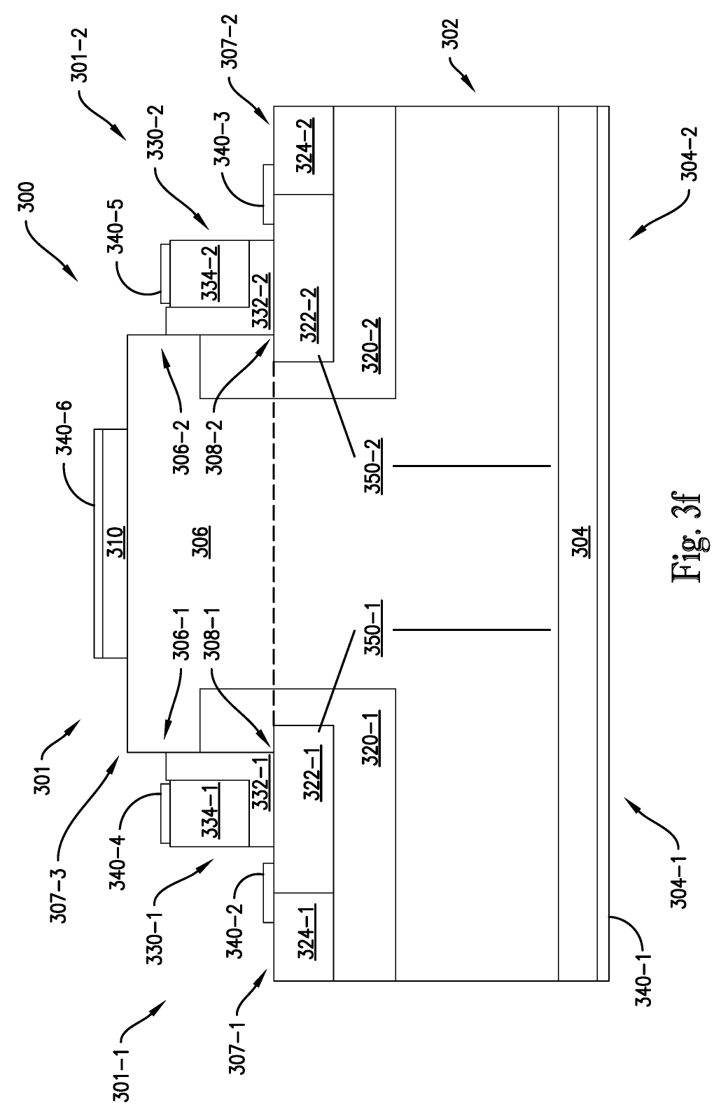

FIG. 2 illustrates a method 200 for forming a semiconductor device including an integrated power MOSFET and SBD (e.g., the device 100 of FIG. 1), in accordance with various examples of the present disclosure. The operations may be performed in the order shown in FIG. 2, or the operations may be performed in a different order. Furthermore, some operations may be performed concurrently as opposed to sequentially. In addition, some operations may be optional. Reference is also made to FIGS. 3a-3e showing the results of certain of the operations of method 200. The device (e.g., the device 300 of FIGS. 3a-3e, to be described in more detail below) formed via the method 200 and any sub-components (e.g., a drain 310, an upward projection 306, a first well/well region 320-1, a second vertical side 306-2, etc.) included therein may be substantially similar or identical to the device 100, or the equivalent, corresponding sub-component (e.g., the drain 110, the upward projection 106, the first well/well region 120-1, the second vertical side 106-2, etc.) of FIG. 1. However, it will be appreciated that the method 200 may be used to form the device 100, as well as numerous other semiconductor devices including integrated SBDs not illustrated/described throughout this disclosure.

Broadly, any feature, portion, area, or volume (doped or undoped) of a semiconductor device formed via the method 200 may be formed via any process suitable to forming said features, portion, area, or volume. For instance, ion implantation and other similar/suitable processes may be used to form wells, sources, bodies, and the like, without limitation. Epitaxial growth and similar/suitable processes may be used to form substrates and initial volumes of semiconductor material. Etching and other similar/suitable processes may be used to remove select portions of the semiconductor material once formed (e.g., to form a trench within the volume of semiconductor material) or to remove portions of oxide, metal or metal alloy layers, without limitation. Deposition and other similar/suitable processes may be used to fill trenches once etched, to form electrical terminals (or contacts), or the like, without limitation.

At operation 210, a volume of semiconductor material may be formed or otherwise provided on a substrate. For example, the volume of semiconductor material 302 illustrated in FIGS. 3a-3f includes a first end (e.g., a top), an opposite second end (e.g., a bottom) spaced vertically beneath the first end, a first side, and an opposite second side spaced laterally, or horizontally, from the first side.

The volume of semiconductor material 302 is formed on a substrate 304. The volume of semiconductor material 302 may be formed on the substrate 304 once the substrate 304 has been formed/provided. The volume of semiconductor material 302 as initially formed (e.g., prior to the formation or implantation of any wells/well regions, sources/source regions, bodies, implants or the like) may comprise or be formed of an N-type material. The substrate 304 may comprise, or be formed of, an N+ material.

Operation 220 includes forming a first well/well region, a first source/source region, and a first body contact at, or near, the first side and the first end of the volume of semiconductor material as well as forming a second well/well region, a second source/source region, and a second body contact at, or near, the second side and the first end of the volume of semiconductor material.

An example of such first and second wells/well regions 320-1, 320-2, first and second sources/source regions 322-1, 322-2, and first and second body contacts 324-1, 324-1 as initially formed within volume of semiconductor material 302 are illustrated in FIG. 3b.

At operation 230, a first etch or other suitable process for removing semiconductor material from an existing volume thereof, is performed. As illustrated in FIG. 3c, the first etch removes at least a portion of the first and second well regions 320-1, 320-2 and the first and second body contacts 324-1, 324-2. Further, the first etch results in the volume of semiconductor material being shaped so as to have an upward projection 306, whereby the first end of the volume of semiconductor material includes a first portion (left portion in the illustrated example) 307-1, a second portion (right portion in the illustrated example) 307-2, and an upper portion (central portion in the illustrated example) 307-3.

In various examples of the present disclosure, the upward projection 306 is directly analogous to upward projection 106 described above. Accordingly, the upward projection 306 of the volume of semiconductor material 302 includes all portions, or regions, of the volume of semiconductor material 302 positioned above the dashed, or dotted, line within the volume of semiconductor material 302, as illustrated in FIGS. 3c-3f. Upward projection 306 may include parts of various features, or regions, typically found in semiconductor devices, such as wells, sources, bodies, and so on, or combinations thereof, without limitation. As illustrated, part of the first and second wells 320-1, 320-2 are included in upward projection 306. It will be appreciated that the dashed line in FIGS. 3c-3f is merely included to serve as a visual aid in distinguishing between the upward projection 306 and the remainder of the volume of semiconductor material 302.

The upward projection 306 presents first and second vertical sides 306-1, 306-2 located at the respective innermost ends of the first and second portions 307-1, 307-1 of the top end of the volume of semiconductor material. The first and second portions 307-1, 307-2 of the first end of the volume of semiconductor material 302 are spaced a first and second dimension from the second end (e.g., the bottom) of the volume of semiconductor material 302. As illustrated, the first and second dimensions are equal. Further, the upper portion 307-3 of the first end is spaced at a third dimension from the second end of the volume of semiconductor material 302, with the third dimension being greater than the first and second dimensions. The upper portion 307-3 of the first end is spaced equally between the first and second sides of the volume of semiconductor material 302. As a result of the third dimension being greater than the first and second dimensions, the upper portion 307-3 of the first end of the volume of semiconductor material 302 is further way from the second end than the first and second portions 307-1, 307-2.

The first portion 307-1 of the top end of the volume of semiconductor material 302 and the first vertical side 306-1 of the upward projection 306 converge to form a first inner corner 308-1. Similarly, the second portion 307-3 of the top end of the volume of semiconductor material 302 and the second vertical side 306-3 of the upward projection 306 converge to form a second inner corner 308-2. While illustrated in FIGS. 3c-3f as being 90^{o} right angles, first and second corners 308-1, 308-2 may be acute or obtuse, and/or may be rounded, chamfered, beveled, and so on, without limitation without departing from the scope of the present disclosure.

The first and second wells, or well regions, 320-1, 320-2 are located adjacent to the first end and the corresponding first or second side of the volume of semiconductor material 302. More particularly, first well 320-1 is located adjacent to the first portion 307-1 of the top of the volume of semiconductor material 302 and the first vertical side 306-1 of the upward projection 306. The first well 320-1 extends along part of the first inner corner 308-1 and along at least part of the first vertical side 306-1 of the upward projection 306. Further, the first well region 320-1 can be thought of as including a vertical well portion and a horizontal well portion, with the vertical well portion extending along at least part of the first vertical side 306-1 of the upward projection 306 and the horizontal well portion being positioned at least partially below the first source region 322-1. The first well 320-1 may comprise, or be formed of, a P-type material.

Analogously, and more particularly, the second well, or well region, 320-2 is located adjacent to the second portion 307-2 of the top of the volume of semiconductor material 302 and the second vertical side 306-2 of the upward projection 306. The second well 320-2 extends along part of the second inner corner 308-1 and along at least part of the second vertical side 306-2 of the upward projection 306. The second well region 320-2 can also be thought of as including a vertical well portion and a horizontal well portion, with the vertical well portion extending along at least part of the second vertical side 306-2 of the upward projection 306 and the horizontal well portion being positioned at least partially below the second source region 322-2. The second well 320-2 may comprise, or be formed of, a P-type material.

The first and second sources, or source regions, 322-1, 322-2 are positioned adjacent to, and extend along, at least part of the corresponding first or second portion 307-1, 307-2 of the first end of the volume of semiconductor material 302. The first and second sources 322-1, 322-2 extend along part of the corresponding first or second inner corner 308-1, 308-2. In various examples of the present disclosure, the first and second sources 322-1, 322-2 extend laterally away from the corresponding first or second side of the volume of semiconductor material and beyond, or past, the corresponding first or second vertical sides 306-1, 306-2 of upward projection 306. The extent to which each of the sources 322-1, 322-2 extends past the corresponding vertical side 306-1, 306-2 may vary within the scope of the present disclosure and account for asymmetries. The first and second sources 322-1, 322-2 may comprise, or be formed of, an N+ material.

The first and second body contacts 324-1, 324-2 extend along the corresponding first or second portion 307-1, 307-2 of the first end of the volume of semiconductor material and between the corresponding source 322-1, 322-2 and the corresponding first or second side of the volume of semiconductor material 302. The first and second body contacts 324-1, 324-2 may comprise, or be formed of, a P+ material.

At operation 240, as illustrated in FIG. 3d, a layer of dielectric material 332 spanning the lateral width (e.g., from the first side to the second side) of the volume of semiconductor material 302 is deposited, or otherwise formed, over the first end thereof. Subsequently, a polysilicon layer 334 spanning the width of the volume of semiconductor material is deposited over the layer of dielectric material 332.

At operation 250, a second etch (or suitable removal process) is performed, the etching resulting in formation of first and second gates 330-1, 330-2. The first and second gates 330-1, 330-2 may be located, or formed, within the corresponding first or second inner corner 308-1, 308-2. The first gate 330-1 includes a layer of dielectric material (e.g., a gate dielectric) 332-1. The layer of dielectric material 332-1 includes (i) an upright dielectric portion extending upwardly, or vertically, along the first vertical side 306-1 of the upward projection 306, and (ii) a lateral dielectric portion extending laterally, or horizontally, along at least part of the first portion 307-1 of the first end of volume of semiconductor material 302. The first gate 330-1 also includes a gate structure 334-1 positioned along the vertical and horizontal dielectric portions. The gate structure 334-1 may comprise, or be formed of, a polysilicon material. In various examples of the present, the vertical dielectric portion of the first gate region 330-1 extends upwardly along the first vertical side 306-1 of the upward projection 306 beyond, or past, the gate structure 334-1.

Analogously, the second gate, or gate region, 330-2 includes a layer of dielectric material 332-2. The layer of dielectric material 332-2 includes (i) an upright dielectric portion extending upwardly, or vertically, along the second vertical side 306-2 of the upward projection 306, and (ii) a lateral dielectric portion extending laterally, or horizontally, along at least part of the second portion 307-2 of the first end of volume of semiconductor material 302. The second gate 330-2 also includes a gate structure 334-2 positioned along the vertical and horizontal dielectric portions. The gate structure 334-2 may comprise, or be formed of, a polysilicon material. In various examples of the present disclosure, the vertical dielectric portion of the second gate region 330-2 extends upwardly along the first vertical side 306-1 of the upward projection 306 beyond, or past, the gate structure 334-2.

Operation 260 includes forming a SBD 310-1 on the upper portion 307-3 of the upper projection 306 of volume of semiconductor material 302. The SBD 310 comprises a Schottky material. In various examples of the present disclosure, the Schottky material may be a metal from the group consisting of: titanium, molybdenum, platinum, chromium, tungsten, aluminum, and combinations thereof. The Schottky material, which is illustrated as being spaced equally between the first and second vertical sides 306-1, 306-2 of the upward projection 306, may be deposited or otherwise provided via any suitable means. The size, shape, and composition of SBD 310 may vary within the parameters described in this paragraph without departing from the scope of the present disclosure.

The SBD 310 is formed over at least a part, or portion, of the upward projection 306. Accordingly, the SBD overlays at least part of the upper portion 307-3 of the first end of the volume of semiconductor material 302.

Finally, a metallization process may be performed to deposit a contact metal, forming electrical terminals, or contacts, 340-1, 340-2, 340-3, 340-4, 340-5, 340-6 to facilitate the application of various electrical signals to the substrate 304, first source or source region 322-1, second source or source region 322-2, first gate or gate region 330-1, second gate or gate region 330-2, and SBD 310, respectively. The effects of applying various, relevant signals to the electrical terminals 340-1, 340-2, 340-3, 340-4, 340-5, 340-6 has already been described in the corresponding section of the description of FIG. 1.

Additional details for each of the operations in the method 200 and/or corresponding to the intermediate steps of forming the device 300 can be found in connection with the descriptions of FIG. 1.

### Feature Combinations

According to various examples of the present disclosure, a semiconductor device may include a volume of semiconductor material, an integrated metal oxide semiconductor field-effect transistor (MOSFET), and an integrated Schottky barrier diode (SBD). The volume of semiconductor material may also include a first end, a second end spaced vertically below the first end, a first side, and a second side spaced laterally from the first side. The volume of semiconductor material may include an upward projection spaced from the first side, such that the first end includes an upper portion spaced from the first side and a first portion located between the upward projection and the first side. The first portion of the first end may be located closer to the second end than the upper portion. The MOSFET may include a first transistor side located adjacent the first side of the volume of semiconductor material. The first transistor side may include a first well located adjacent the first end of the volume of semiconductor material, and a first gate. The SBD may comprise a Schottky material positioned over at least part of the upward projection.

In combination with the previous example, the upward projection may include a first vertical side which extends upwardly from the first portion of the first end and cooperates therewith to define a first inner corner. The first well may extend along part of the first inner corner.

In combination with any of the previous examples, the first transistor side may include a first source extending along part of a first inner corner.

In combination with any of the previous examples, the first well may extend along part of a first vertical side of the upward projection, and a first source may extend along at least part of the first portion of the first end.

In combination with any of the previous examples, a first source may extend laterally from the first side beyond a first inner corner.

In combination with any of the previous examples, the first well may include a vertical well portion extending along a first vertical side of the upward projection. The first well may further include a horizontal well portion at least in part positioned below a first source.

In combination with any of the previous examples, the first transistor side may include a first body contact extending along the first portion of the first end between a first source and the first side of the volume of semiconductor material.

In combination with any of the previous examples, the first transistor side may include a drain located at the second end of the volume of semiconductor material, the first well may include a P-type material, a first source may include an N+ material, a first body contact may include a P+ material, the first drain may include an N+ material, the first transistor side including a first channel that extends along an N-type material between the first source and the first drain.

In combination with any of the previous examples, a first gate may be located at a first inner corner.

In combination with any of the previous examples, a first gate may include a layer of dielectric material, the layer of dielectric material may include a vertical dielectric portion extending along a first vertical side of the upward projection, the layer of dielectric material further including a horizontal dielectric portion extending along at least part of the first portion of the first end.

In combination with any of the previous examples, a first gate may include a gate structure positioned along vertical and horizontal dielectric portions. The vertical dielectric portion may extend upwardly along a first vertical side of the upward projection beyond the gate structure.

In combination with any of the previous examples, a gate structure may include a polysilicon material.

In combination with any of the previous examples, the Schottky material may overlay at least part of the upper portion of the first end.

In combination with any of the previous examples, the upward projection may be spaced from the second side of the volume of semiconductor material such that the first end includes a second portion located between the upward projection and the second side, with the second portion of the first end being located closer to the second end than the upper portion. The upward projection may include first and second vertical sides that extend upwardly from the first and second portions of the first end, respectively. The Schottky material may be spaced equally between the first and second sides of the upward projection.

In combination with any of the previous examples, the upward projection may be spaced from the second side of the volume of semiconductor material such that the first end includes a second portion located between the upward projection and the second side, with the second portion of the first end being located closer to the second end than the upper portion.

In combination with any of the previous examples, the first portion of the first end may be spaced a first dimension from the second end, and a second portion of the first end may be spaced a second dimension from the second end.

In combination with an of the previous examples, the first and second dimensions may be equal.

In combination with any of the previous examples, the upper portion of the first end may be spaced equally between the first and second sides.

In combination with any of the previous examples, the MOSFET may include a second transistor side adjacent the second side of the volume of semiconductor material. The second transistor side may include a second well located adjacent the first end of the volume of semiconductor material and a second gate. The upward projection may include a first vertical side which extends upwardly from the first portion of the first end and cooperates therewith to define a first inner corner, and the upward projection may further include a second vertical side which extends upwardly from the second portion of the first end and cooperates therewith to define a second inner corner. The first well may extend along part of the first inner corner, and the second well may extend along part of the second inner corner.

In combination with any of the previous examples, the first transistor side may include a first source extending along part of a first inner corner, a second transistor side may include a second source extending along part of a second inner corner, the first gate may be located within the first corner, and a second gate may be located within the second inner corner.

### General Considerations

In this description, references to “one embodiment”, “an embodiment”, “embodiments”, “an example”, “one example”, or “examples” mean that the feature or features being referred to are included in at least one embodiment or example of the technology. Separate references to “one embodiment,” “an embodiment,” “embodiments,” “an example,” “one example,” or “examples” in this description do not necessarily refer to the same embodiment or example and are also not mutually exclusive unless so stated and/or except as will be readily apparent to those skilled in the art from the description. For example, a feature, structure, act, etc. described in one embodiment may also be included in other embodiments but is not necessarily included. Thus, the current technology can include a variety of combinations and/or integrations of the embodiments described herein.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein, unless otherwise expressly stated and/or readily apparent to those skilled in the art from the description.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

The patent claims at the end of this patent application are not intended to be construed under 35 U.S.C. § 112(f) unless traditional means-plus-function language is expressly recited, such as “means for” or “step for” language being explicitly recited in the claim(s).

Although the invention has been described with reference to the embodiments illustrated in the attached drawing figures, it is noted that equivalents may be employed and substitutions made herein without departing from the scope of the invention as recited in the claims.

While the present disclosure has been described herein with respect to certain illustrated examples, those of ordinary skill in the art will recognize and appreciate that the present disclosure is not so limited. Rather, many additions, deletions, and modifications to the illustrated and described examples may be made without departing from the scope of the disclosure as hereinafter claimed along with their legal equivalents. In addition, features from one example may be combined with features of another example while still being encompassed within the scope of the disclosure as contemplated by the inventors.

Although described herein with regard or in relation to one or more particular kinds of electronic devices (e.g., junction field-effect transistor, metal oxide semiconductor field-effect transistor), the technology may be more broadly applicable to one or more other kinds of electronic devices as well.

One with ordinary skill in the art will recognize that the technology described herein may, when applicable, be implemented in enhancement mode or depletion mode.

Further, the technology described herein may, when applicable, be implemented as an N-channel or P-channel device, wherein, in general, regions that are N-doped or P-doped in N-channel implementations may be, respectively, P-doped or N-doped in P-channel implementations.

Additionally, the various example materials identified herein may, in some aspects, be replaced and/or supplemented with substantially any other suitable material. For example, gate material may include polysilicon, a metal or alloy of metals, or other suitable material; gate oxide or dielectric may include silicon dioxide (SiO₂), aluminum oxide (Al₂O₃), hafnium dioxide (HfO₂), silicon nitride (Si₃N₄), or other suitable material; and semiconductor material may include silicon carbide (SiC), gallium nitride (GaN), zinc oxide (ZnO), or other suitable material.

Additionally, in general, unless otherwise specified or unless one with ordinary skill in the art would understand otherwise, doping characterized as "++" (e.g., P++) will have a relatively higher concentration of dopants than "+" (e.g., P+) doping, "+" doping will have a relatively higher concentration than "-well" (e.g., P-well) doping, and "-well" doping will have a relatively higher concentration of doping than "-" (e.g., P-) doping. In general, doping concentrations (typically measured in parts-per-cubic-centimeter) for contact implants (e.g., sources, drains, body contacts) may be approximately between 5x10^18 and 1x10^22; doping concentrations for channel and threshold forming implants (e.g., P-wells) may be approximately between 5x10^15 and 5x10^17; doping concentrations for shielding implants may be approximately between 5x10^17 and 5x10^19; and doping concentrations for conductivity improvement implants (e.g., N- doping in the junction field-effect transistor neck region of a metal oxide semiconductor field-effect transistor) may be approximately between 1x10^17 and 1x10^19.

Relatedly, a structure or region may contain two or more different doping doses. In various examples, dopant concentrations within a given structure or region may vary within the example range described above for the corresponding region type. Dopant concentration may vary according to a gradient that gradually decreases as the depth of the implant increases. Further, one with ordinary skill in the art will recognize that some P-wells may contain a lower dose P-well portion and a higher dose unclamped inductive switching portion. Dopant concentration variation within a given structure or region may result from normal manufacturing variance, may be by design, or may otherwise arise without departing from the spirit of the present disclosure.

What is claimed is:

1. A semiconductor device comprising:
a volume of semiconductor material including a first end, a second end spaced vertically below the first end, a first side, and a second side spaced laterally from the first side,
the volume of semiconductor material including an upward projection spaced from the first side, such that the first end includes an upper portion spaced from the first side and a first portion located between the upward projection and the first side, with the first portion of the first end being located closer to the second end than the upper portion;
an integrated metal oxide semiconductor field-effect transistor (MOSFET) including –
a first transistor side located adjacent the first side of the volume of semiconductor material, the first transistor side including –
a first well located adjacent the first end of the volume of semiconductor material, and
a first gate; and
an integrated Schottky barrier diode (SBD) comprising a Schottky material positioned over at least part of the upward projection.

2. The semiconductor device of claim 1,
the upward projection including a first vertical side which extends upwardly from the first portion of the first end and cooperates therewith to define a first inner corner,
the first well extending along part of the first inner corner.

3. The semiconductor device of claim 2,
the first transistor side including a first source extending along part of the first inner corner.

4. The semiconductor device of claim 3,
the first well extending along part of the first vertical side of the upward projection,
the first source extending along at least part of the first portion of the first end.

5. The semiconductor device of claim 4,
the first source extending laterally away from the first side beyond the first inner corner.

6. The semiconductor device of claim 5,
the first well including a vertical well portion extending along the first vertical side of the upward projection,
the first well further including a horizontal well portion at least in part positioned below the source.

7. The semiconductor device of claim 4,
the first transistor side including a first body contact extending along the first portion of the first end between the first source and the first side of the volume of semiconductor material.

8. The semiconductor device of claim 7,
the first transistor side including a first drain located at the second end of the volume of semiconductor material,
the first well including a P-type material,
the first source including an N+ material,
the first body contact including a P+ material,
the first drain including an N+ material,
the first transistor side including a first channel that extends along an N-type material between first source and the first drain.

9. The semiconductor device of claim 4,
the first gate being located within the first inner corner.

10. The semiconductor device of claim 9,
the first gate including a layer of dielectric material,
the layer of dielectric material including a vertical dielectric portion extending along the first vertical side of the upward projection,
the layer of dielectric material further including a horizontal dielectric portion extending along at least part of the first portion of the first end.

11. The semiconductor device of claim 10,
the first gate including a gate structure positioned along the vertical and horizontal dielectric portions,
the vertical dielectric portion extending upwardly along the first vertical side of the upward projection beyond the gate structure.

12. The semiconductor device of claim 11,
the gate structure including a polysilicon material.

13. The semiconductor device of claim 1,
the Schottky material overlying at least part of the upper portion of the first end.

14. The semiconductor device of claim 13,
the upward projection being spaced from the second side of the volume of semiconductor material, such that the first end includes a second portion located between the upward projection and the second side, with the second portion of the first end being located closer to the second end than the upper portion,
the upward projection including first and second vertical sides that extend upwardly from the first and second portions of the first end, respectively,
the Schottky material being spaced equally between the first and second vertical sides of the upward projection.

15. The semiconductor device of claim 1,
the upward projection being spaced from the second side of the volume of semiconductor material, such that the first end includes a second portion located between the upward projection and the second side, with the second portion of the first end being located closer to the second end than the upper portion.

16. The semiconductor device of claim 15,
the first portion of the first end being spaced a first dimension from the second end, and the second portion of the first end being spaced a second dimension from the second end.

17. The semiconductor device of claim 16,
the first and second dimensions being equal.

18. The semiconductor device of claim 17,
the upper portion of the first end being spaced equally between the first and second sides.

19. The semiconductor device of claim 15,
the MOSFET including –
a second transistor side adjacent the second side of the volume of semiconductor material, the second transistor side including –
a second well located adjacent the first end of the volume of semiconductor material, and
a second gate,
the upward projection including a first vertical side which extends upwardly from the first portion of the first end and cooperates therewith to define a first inner corner,
the upward projection further including a second vertical side which extends upwardly from the second portion of the first end and cooperates therewith to define a second inner corner,
the first well extending along part of the first inner corner,
the second well extending along part of the second inner corner.

20. The semiconductor device of claim 19,
the first transistor side including a first source extending along part of the first inner corner,
the second transistor side including a second source extending along part of the second inner corner,
the first gate being located within the first inner corner,
the second gate being located within the second inner corner.
